(19) United States
(12) Patent Application Publication
(10) Pub. No.: US 2020/0335871 A1
(43) Pub. Date: Oct. 22, 2020

(54) DIPOLE ANTENNA AND UNMANNED AERIAL VEHICLE

(71) Applicant: SZ DJI TECHNOLOGY CO., LTD., Shenzhen (CN)

(72) Inventors: Dong LI, Shenzhen (CN); Zhitao GAO, Shenzhen (CN)

(21) Appl. No.: 16/919,708

(22) Filed: Jul. 2, 2020

Related U.S. Application Data
(63) Continuation of application No. PCT/CN2018/071631, filed on Jan. 5, 2018.

(51) Int. Cl. H01Q 9/28; B64C 39/02; B64C 1/36; H05K 1/02; H05K 1/11

(52) U.S. Cl. CPC H01Q 9/28; B64C 39/024; B64C 1/36; H05K 2201/09009; H05K 1/111; B64C 2201/00; H05K 2201/10098; H05K 1/0243

(57) ABSTRACT

An unmanned aerial vehicle (UAV) includes a transceiver control device, and a dipole antenna electrically coupled to the transceiver control device and configured to communicate with a ground control station under a control of the transceiver control device. The dipole antenna includes a printed circuit board (PCB), a first oscillator spirally wound around an outer side of the PCB, and a second oscillator. The first oscillator and the second oscillator form a half-wave dipole antenna.

### CROSS-REFERENCE TO RELATED APPLICATION

This application is a continuation of International Application No. PCT/CN2018/071631, filed Jan. 5, 2018, the entire content of which is incorporated herein by reference.

### TECHNICAL FIELD

The present disclosure relates to the unmanned aerial vehicle technology field, and more particularly, to a dipole antenna and an unmanned aerial vehicle.

### BACKGROUND

In recent years, with the rapid development of unmanned aerial vehicle (UAV) technology, unmanned aerial vehicles have been more and more widely used in various applications. For example, a UAV is configured for transporting goods in a transportation industry, measuring farmland in an agricultural field, or mapping in a mapping field. In the above described applications, an antenna is needed on the UAV to receive a signal from outside or send a signal to outside. On the other side, antennas currently provided at UAVs have large sizes and cannot meet needs for miniaturization of UAVs.

### SUMMARY

In accordance with the present disclosure, there is provided an unmanned aerial vehicle (UAV) including a transceiver control device, and a dipole antenna electrically coupled to the transceiver control device and configured to communicate with a ground control station under a control of the transceiver control device. The dipole antenna includes a printed circuit board (PCB), a first oscillator spirally wound around an outer side of the PCB, and a second oscillator. The first oscillator and the second oscillator form a half-wave dipole antenna.

### BRIEF DESCRIPTION OF THE DRAWINGS

In order to more clearly explain the embodiments of the present disclosure, the drawings used in the description of the embodiments will be briefly introduced below. Obviously, the drawings in the following description are some embodiments of the present disclosure. For those of ordinary skill in the art, other drawings can be obtained based on these drawings without creative efforts.

FIG. 1 is a schematic structural diagram of an example dipole antenna consistent with the present disclosure.

FIG. 2 is another schematic structural diagram of the example dipole antenna consistent with the present disclosure.

FIG. 3 is a schematic structural diagram of another example dipole antenna consistent with the present disclosure.

FIG. 4 is another schematic structural diagram of the other example dipole antenna consistent with the present disclosure.

FIG. 5 is a front view of a second oscillator of a further example dipole antenna consistent with the present disclosure.

FIG. 6 is a top view of the second oscillator of the further example dipole antenna consistent with the present disclosure.

FIG. 7 is a left side view of the second oscillator of the further example dipole antenna consistent with the present disclosure.

FIG. 8 is a three-dimension diagram of the second oscillator of the further example dipole antenna consistent with the present disclosure.

FIG. 9 is a measured efficiency diagram of the further example dipole antenna consistent with the present disclosure.

FIG. 10 is a measured pattern of the further example dipole antenna consistent with the present disclosure.

FIG. 11 is a front view of a second oscillator of a still further example dipole antenna consistent with the present disclosure.

FIG. 12 is a top view of the second oscillator of the still further example dipole antenna consistent with the present disclosure.

FIG. 13 is a left side view of the second oscillator of the still further example dipole antenna consistent with the present disclosure.

FIG. 14 is a three-dimension diagram of the second oscillator of the still further example dipole antenna consistent with the present disclosure.

FIG. 15 is a measured efficiency diagram of the still further example dipole antenna consistent with the present disclosure.

FIG. 16 is a measured gain diagram of the still further example dipole antenna according to one embodiment of the present disclosure.

FIG. 17 is a measured pattern of the still further example dipole antenna consistent with the present disclosure.

FIG. 18 is a schematic structural diagram of an example unmanned aerial vehicle consistent with the present disclosure.

FIG. 19 is a schematic structural diagram of another example unmanned aerial vehicle consistent with the present disclosure.

### REFERENCE NUMERALS

100—Dipole antenna
10—Printed circuit board (PCB)
20—First oscillator
30—Second oscillator
11—First groove
40—Coaxial line
41—Inner conductor
42—Outer conductor
21—Feeding end of the first oscillator
31—Feeding end of the second oscillator
12—First pad
13—Second pad
14—Second groove
15—First positioning member
16—Second positioning member
17—Stopper
200—Transceiver control device
300—Flight controller
400—Camera

### DETAILED DESCRIPTION OF THE EMBODIMENTS

To better illustrate the objectives, technical solutions, and advantages of embodiments of the present disclosure, technical solutions of the present disclosure will be described with reference to the drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

With its development, unmanned aerial vehicle (UAV) has been widely used in fields such as mapping, farmland planning, or electric power inspection, etc., where precise communication between the UAV and outside is needed. In order to communicate accurately with outside, a relatively large size is needed for an antenna provided at the UAV to improve transceiver efficiency and radiation coverage performance of the antenna, which on the other side increases the size of the UAV and cannot meet a need for miniaturization of the UAV.

To solve the above described technical problem, the present disclosure provides a dipole antenna including two oscillators and a printed circuit board (PCB). One oscillator includes a helical antenna that is spirally wound around the outer side of the PCB. The two oscillators together form a half-wave dipole antenna. The dipole antenna has a small size and high radiation efficiency, and can meet the need for the miniaturization of the UAV.

Technical solutions of the present disclosure will be described in detail below with specific embodiments. The specific embodiments can be combined with each other, and same or similar concepts or processes are not repeated in some embodiments.

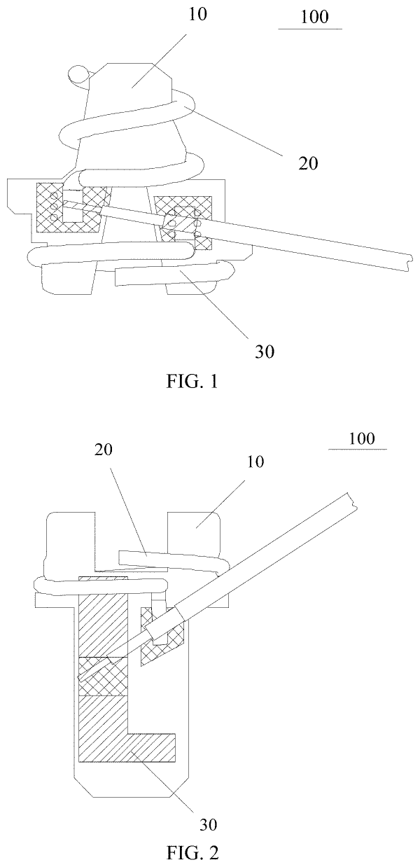

FIG. 1 is a schematic structural diagram of an example of a dipole antenna 100 consistent with the present disclosure. FIG. 2 is another schematic structural diagram of the dipole antenna 100. As shown in FIG. 1 and FIG. 2, the dipole antenna 100 includes a PCB 10, a first oscillator 20, and a second oscillator 30, where the first oscillator 20 includes a helical antenna that is spirally wound around an outer side of the PCB 10, and the first oscillator 20 and the second oscillator 30 together form a half-wave dipole antenna.

In some embodiments, the UAV may be a UAV for plant protection, a UAV for aerial photography, or a UAV for mapping, etc., and the UAV is not limited to a specific type.

In some embodiments, as shown in FIG. 1 and FIG. 2, the dipole antenna 100 includes the PCB 10, the first oscillator 20, and the second oscillator 30, where the first oscillator 20 includes a helical antenna that is spirally wound around the outer side of the PCB 10, and the first oscillator 20 and the second oscillator 30 together form the half-wave dipole antenna. The half-wave dipole antenna has a high operation efficiency in an operation frequency band and a good omnidirectional radiation performance in a horizontal plane.

In addition, the first oscillator 20 is wound around the outer side of the PCB 10, so that an overall size of the antenna is reduced and the antenna can be provided at a micro UAV, thereby meeting a need for the miniaturization of the UAV on the premise of ensuring a high radiation efficiency of the dipole antenna 100.

In some embodiments, as shown in FIG. 1, the second oscillator 30 is the same as the first oscillator 20, and may also include a helical antenna that is spirally wound around an outer side of the PCB 10. For example, the first oscillator 20 is wound around an upper part of the PCB 10 and the second oscillator 30 is wound around a lower part of the PCB 10, or the first oscillator 20 is wound around a lower part of the PCB 10 and the second oscillator 30 is wound around an upper part of the PCB 10. Lengths of the first oscillator 20 and the second oscillator 30 are both equivalent to ¼ wavelength, and a total length of the first and second oscillators 20 and 30 is ½ wavelength. Thus, the first and second oscillators 20 and 30 form a half-wave dipole antenna.

That is, in some embodiments, the first oscillator 20 and the second oscillator 30 of the dipole antenna 100 include helical antennas wound around the outer side of the PCB 10, which further reduces a volume of the antenna and meets the need for miniaturization of the UAV. In addition, the high radiation efficiency of the dipole antenna 100 allows the UAV to communicate accurately with other devices through the dipole antenna 100, thereby improving a reliability of the UAV.

In some embodiments, as shown in FIG. 2, the second oscillator 30 includes a planar printed antenna (PPA). For example, a PPA is provided at the PCB 10 as the second oscillator 30. The first oscillator 20 and the second oscillator 30 together form a half-wave dipole antenna. The dipole antenna 100 has a high radiation efficiency. Further, the second oscillator 30 of the dipole antenna 100 is directly printed on the PCB 10, which not only reduces an overall size of the antenna, but also makes the structure of the antenna more compact, thereby improving a structural stability of the dipole antenna 100.

In some embodiments, the second oscillator 30 may include an oscillator with another structure, e.g., a metal wire. The second oscillator 30 is not limited to a specific structure as long as it can form a half-wave dipole antenna together with the first oscillator 20.

The first oscillator 20 and the second oscillator 30 together form the half-wave dipole antenna, and an input impedance of the half-wave dipole antenna is a pure impedance, in which case a power reflection of an end of a feeding line is zero, and there is no standing wave on the feeding line. A change of the input impedance of the antenna with frequency is relatively stable, and hence a relatively good performance of the antenna can be achieved.

In some embodiments, a process of using the dipole antenna 100 includes a ground control station sending a control signal to the UAV in a form of an electromagnetic wave to instruct the UAV to further ascend 100 mm vertically from a current altitude. The first oscillator 20 and the second oscillator 30 of the dipole antenna 100 simultaneously receive the control signal and send the control signal to a flight controller of the UAV. According to the control signal, the flight controller controls a power system of the UAV to drive the UAV to further ascend 100 mm vertically from the current altitude.

The dipole antenna 100 can receive a linearly polarized electromagnetic wave or a circularly polarized electromagnetic wave, and has a wide reception range.

In some embodiments, the dipole antenna includes a PCB, a first oscillator, and a second oscillator, where the first oscillator includes a helical antenna that is spirally wound around an outer side of the PCB, and the first oscillator and the second oscillator together form the half-wave dipole antenna. The dipole antenna has a small size, and is convenient to be provided at a micro UAV, thereby meeting a need for miniaturization of the UAV. In addition, the dipole antenna formed by the first oscillator and the second oscillator has a high radiation efficiency, which allows the UAV to communicate accurately with outside through the dipole antenna, thereby improving a reliability of the UAV.

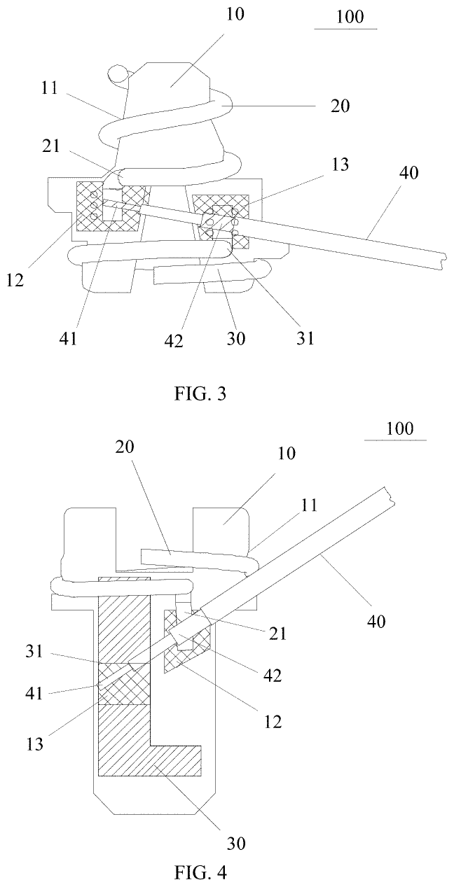

FIG. 3 is a schematic structural diagram of another example of the dipole antenna 100 consistent with the present disclosure. FIG. 4 is another schematic structural diagram of the dipole antenna. As shown in FIG. 3 and FIG. 4, the first oscillator 20 is spirally wound around an upper part of the PCB 10 and extends toward an upper end of the PCB 10.

In some embodiments, the PCB 10 includes two parts, i.e., an upper part and a lower part. As shown in FIG. 3 and FIG. 4, the first oscillator 20 is provided at the upper part of the PCB 10, in some embodiments, is spirally wound around the upper part of the PCB 10 and extends toward the upper end of the PCB 10, which facilitates a connection and fixing of the first oscillator 20 to the PCB 10, and facilitates signal reception of the first oscillator 20.

In some embodiments, the first oscillator 20 includes a first spiral metal wire. For example, a conductive metal wire of copper, aluminum, gold, or silver, etc. is wound into a spiral shape to form the first oscillator 20.

In some embodiments, to facilitate obtaining the first spiral metal wire, the first spiral metal wire may be a metal spring, that is, an existing metal spring can be directly used as the first oscillator 20 to reduce a manufacturing cost of the first oscillator 20.

Further, with reference to FIG. 3 and FIG. 4, in order to improve the stability of the first oscillator 20, a first groove 11 is provided at a side wall of the upper part of the PCB 10, and the first spiral metal wire is fixed in the first groove 11.

In some embodiments, when the first spiral metal wire (i.e., the first oscillator 20) is spirally wound around the upper part of the PCB 10, the first spiral metal wire contacts the side wall of the upper part of the PCB 10. A plurality of first grooves 11 may be provided at the side wall of the upper part of the PCB 10, and when the first spiral metal wire is wound around the upper part of the PCB 10, the first spiral metal wire may be fixed in the first grooves 11. A reliable connection between the first spiral metal wire and the PCB 10 is achieved, which improves the stability of the first oscillator and avoids a problem that the dipole antenna 100 cannot be used caused by the first oscillator 20 being broken during a vibration of the UAV.

It should be noted that the first grooves 11 are spirally distributed on the side wall of the upper part of the PCB 10. For example, a first side wall of the PCB 10 is provided with three first grooves 11 in sequence, namely a, b, and c. Correspondingly, a second side wall of the PCB 10 is provided with three first grooves 11 in sequence, namely d, e, and f. According to an order of a-d-b-e-c-f, the first grooves 11 on the first side wall and the second side wall are connected, and a connecting line thereof forms a spiral line that has the same rotation direction as the first spiral metal wire. During manufacturing the first oscillator 20, a straight metal wire may be used and wound around the first grooves 11 in the upper part of the PCB 10 to form the first spiral metal wire.

In some embodiments, when the PCB 10 is a column, e.g., a cylinder or a truncated cone, in order to further improve the fixing stability of the first oscillator 20, an entire outer wall of the upper part of the PCB 10 may be provided with a spiral-shaped first groove 11, and the first spiral metal wire is fixed in the first groove 11.

In some embodiments, the first spiral metal wire may be bonded in the first groove 11. In some embodiments, the first spiral metal wire may also be welded in the first groove 11 to make the connection of the first spiral metal wire and the PCB 10 firmer.

In some embodiments, a shape of the first spiral metal wire is closely related to a shape of the upper part of the PCB 10. For example, if the upper part of the PCB 10 is rectangular, the first spiral metal wire is cylindrical. If the upper part of the PCB 10 is a trapezoid with a larger upper size and a smaller lower size, the first spiral metal wire is a truncated cone with a larger upper size and a smaller lower size. If the upper part of the PCB 10 is a trapezoid with a smaller upper size and a larger lower size, the first spiral metal wire is a truncated cone with a smaller upper size and a larger lower size. In some embodiments, the upper part of the PCB 10 is a polygon of another shape, and a corresponding front projection of the first spiral metal wire is the same as a projection shape of the PCB 10.

In some embodiments, the shape of the upper part of the PCB 10 and the specific shape of the first spiral metal wire are not limited, and are determined according to an actual need.

In some embodiments, a top cover may be provided at the outer side of the first oscillator 20 to protect the first oscillator 20.

Further, referring to FIG. 3 and FIG. 4, the first oscillator 20 and the second oscillator 30 are fed through a coaxial line 40. That is, a feeding end 21 of the first oscillator 20 and a feeding end 31 of the second oscillator 30 are both coupled to the coaxial line 40. The coaxial line 40 transmits a signal received by the first oscillator 20 and the second oscillator 30 to a transceiver control device of the UAV, or transmits a signal from the transceiver control device to the first oscillator 20 and the second oscillator 30, so that the first oscillator 20 and the second oscillator 30 transmit the signal.

In some embodiments, the first oscillator 20 and the second oscillator 30 are balancedly fed through the coaxial line 40, and hence are convenient to connect, simple to manufacture, easy to match, and have a relatively low parasitic radiation, thereby reducing a manufacturing cost of the antenna and further improving a radiation efficiency of the antenna.

In some embodiments, the coaxial line may be a silver-tin cable.

This embodiment does not limit methods for connecting the first oscillator 20 and the second oscillator 30 with the coaxial line 40, that is, the first oscillator 20 and the second oscillator 30 may be connected with the coaxial line 40 directly or through another conductive connector.

In some embodiments, the feeding end 21 of the first oscillator 20 and the feeding end 31 of the second oscillator 30 are soldered to the coaxial line 40.

In some embodiments, as shown in FIG. 3 and FIG. 4, the PCB 10 is provided with a first pad 12 and a second pad 13. The feeding end 21 of the first oscillator 20 and the coaxial line 40 are both soldered on the first pad 12, so that the first oscillator 20 is coupled to the coaxial line 40 through the first pad 12. The feeding end 31 of the second oscillator 30 and the coaxial line 40 are both soldered on the second pad 13, so that the second oscillator 30 is coupled to the coaxial line 40 through the second pad 13.

The first pad 12 and the second pad 13 may be located on different sides of the PCB 10. For example, the first pad 12 is located on a front of the PCB 10 and the second pad 13 is located on a back of the PCB 10.

In some embodiments, in order to facilitate connecting the first oscillator 20 and the second oscillator 30 with the coaxial line 40, the first pad 12 and the second pad 13 are located on a same side of the PCB 10.

In some embodiments, a specific manner of connecting the first oscillator 20 and the second oscillator 30 with the coaxial line 40 may include connecting the feeding end 21 of the first oscillator 20 to an inner conductor 41 of the coaxial line 40 and connecting the feeding end 31 of the second oscillator 30 to an outer conductor 42 of the coaxial line 40.

In some embodiments, a specific manner of connecting the first oscillator 20 and the second oscillator 30 with the coaxial line 40 may include connecting the feeding end 21 of the first oscillator 20 to an outer conductor 42 of the coaxial line 40 and connecting the feeding end 31 of the second oscillator 30 to an inner conductor 41 of the coaxial line 40.

In the dipole antenna provided by the embodiment, the first oscillator is spirally wound around the upper part of the PCB and extends toward the upper end of the PCB, which facilitates the connection and fixing of the first oscillator to the PCB. Further, in order to improve the stability of the first oscillator, the first groove is provided at the side wall of the upper part of the PCB, and the first spiral metal wire is fixed in the first groove, thereby improving the stability of the connection between the first oscillator and the PCB, and improving the operation stability of the dipole antenna. In addition, the first oscillator and the second oscillator are fed through the coaxial line, and hence are convenient to connect, simple to manufacture, easy to match, and have a relatively low parasitic radiation, thereby reducing a manufacturing cost of the antenna and further improving a radiation efficiency of the antenna.

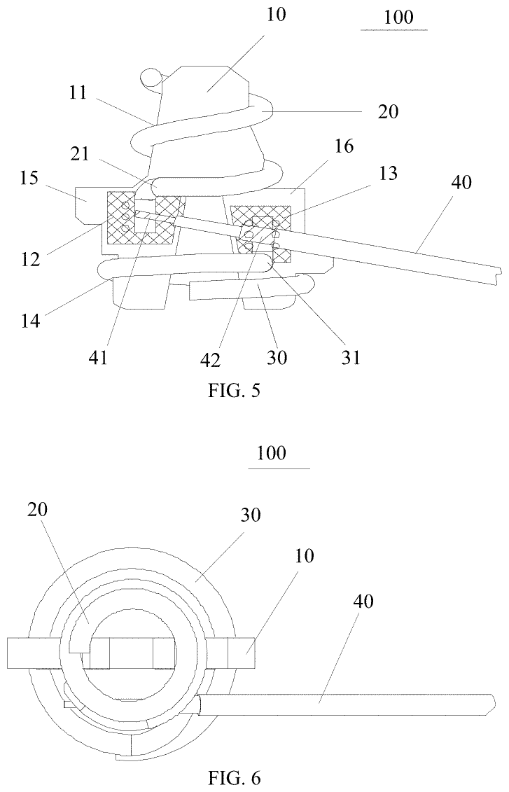

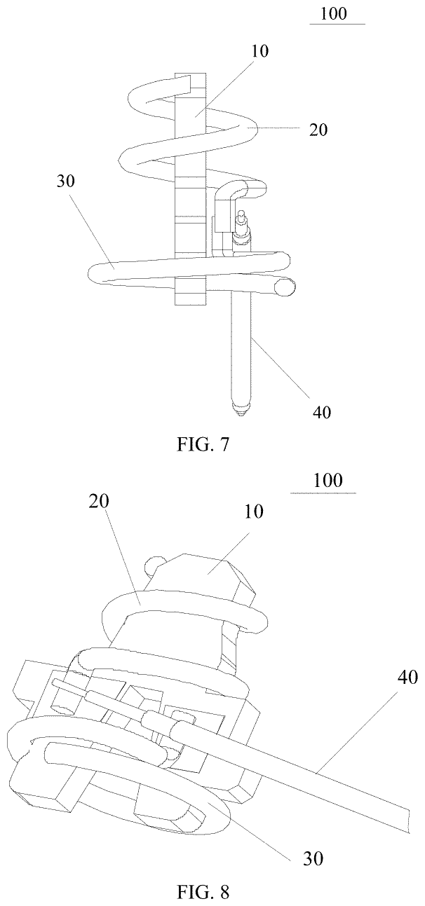

FIG. 5 is a front view of the second oscillator in another example of the dipole antenna 100 consistent with the present disclosure. FIG. 6 is a top view of the second oscillator. FIG. 7 is a left side view of the second oscillator. FIG. 8 is a three-dimension diagram of the second oscillator.

As shown in FIGS. 5-8, the second oscillator 30 is spirally wound around the outer side of the PCB 10. For example, when the first oscillator 20 is wound around the upper part of the PCB, the second oscillator 30 may be wound around a lower end part of the PCB. When the first oscillator 20 is wound around the lower part of the PCB, the second oscillator 30 may be wound around an upper end part of the PCB.

In some embodiments, as shown in FIGS. 5-8, the second oscillator 30 is spirally wound around the lower part of the PCB 10 and extends toward the lower end of the PCB 10. In some embodiments, the second oscillator 30 includes a feeding end 31 and a free end, where the feeding end 31 is fixed in a middle of the PCB 10, and the free end spirally extends from the middle toward the lower end of the PCB 10. The first oscillator 20 is spirally wound around the upper part of the PCB 10 and extends toward the upper end of the PCB 10.

As shown in FIGS. 5-8, the first oscillator 20 and the second oscillator 30 are symmetrical with respect to the middle of the PCB 10. The feeding end 21 of the first oscillator 20 and the feeding end 31 of the second oscillator 30 are both located in the middle of the PCB 10, so as to achieve a balanced feeding to the first oscillator 20 and the second oscillator 30. A 3D pattern of the balancedly-fed dipole antenna 100 is an apple shape that has a good out-of-roundness in a horizontal plane, thereby improving an omnidirectional radiation performance of the dipole antenna 100 in the horizontal plane.

In some embodiments, the second oscillator 30 includes a second spiral metal wire. For example, a conductive metal wire of copper, aluminum, gold, or silver, etc. is wound into a spiral shape to form the second oscillator 30.

In some embodiments, to facilitate obtaining the second spiral metal wire, the second spiral metal wire may be a metal spring, that is, an existing metal spring can be directly used as the second oscillator 30 to reduce a manufacturing cost of the second oscillator 30.

Further, referring to FIG. 5 and FIG. 8, in order to improve the stability of the second oscillator 30, a second groove 14 is provided at a side wall of the lower part of the PCB 10, and the second spiral metal wire is fixed in the second groove 14.

In some embodiments, when the second spiral metal wire is spirally wound around the lower part of the PCB 10, the second spiral metal wire contacts the side wall of the lower part of the PCB 10. A plurality of second grooves 14 may be provided at the side wall of the lower part of the PCB 10, and when the second spiral metal wire is wound around the lower part of the PCB 10, the second spiral metal wire may be fixed in the second groove 14. A reliable connection between the second spiral metal wire and the PCB 10 is achieved, which improves the stability of the second oscillator 30.

It should be noted that each second groove 14 is spirally distributed on the side wall of the lower part of the PCB 10. The above described first groove 11 can be referred to for a specific distribution process, and will not be repeated here.

During manufacturing the second oscillator 30, a straight metal wire may be used and wound around the second groove 14 in the lower part of the PCB 10 to form the second spiral metal wire.

In some embodiments, when the PCB 10 is a column, e.g., a cylinder or a truncated cone, in order to further improve the fixing stability of the second oscillator 30, an entire outer wall of the lower part of the PCB 10 may be provided with a spiral-shaped second groove 14, and the second spiral metal wire is fixed in the second groove 14.

In some embodiments, the second spiral metal wire may be bonded in the second groove 14. In some embodiments, the second spiral metal wire may also be welded in the second groove 14 to make the connection of the second spiral metal wire and the PCB 10 firmer.

In some embodiments, a shape of the second spiral metal wire is closely related to a shape of the lower part of the PCB 10. For example, if the lower part of the PCB 10 is rectangular, the second spiral metal wire is cylindrical. If the lower part of the PCB 10 is a trapezoid with a larger upper size and a smaller lower size, the second spiral metal wire is a truncated cone with a larger upper size and a smaller lower size. If the lower part of the PCB 10 is a trapezoid with a smaller upper size and a larger lower size, the second spiral metal wire is a truncated cone with a smaller upper size and a larger lower size. In some embodiments, the lower part of the PCB 10 is a polygon of another shape, and a corresponding front projection of the second spiral metal wire is the same as a projection shape of the PCB 10.

In some embodiments, the shape of the lower part of the PCB 10 and the specific shape of the second spiral metal wire are not limited, and are determined according to an actual need.

In some embodiments, as shown in FIGS. 5-8, the PCB 10 includes a trapezoidal PCB, the first oscillator 20 includes a first conical spiral metal wire, and the second spiral metal wire (i.e., the second oscillator 30) includes a second conical spiral metal wire, where the first conical spiral metal wire is wound around the upper part of the PCB 10, and the second conical spiral metal wire is wound around the lower part of the PCB 10.

As shown in FIGS. 5-8, the dipole antenna 100 formed by the first oscillator 20 and the second oscillator 30 has a truncated cone shape.

In some embodiments, the PCB 10 is a trapezoidal board with a larger top and a smaller bottom, that is, a width of the upper part of the PCB 10 is greater than a width of the lower part of the PCB 10. In these embodiments, the dipole antenna 100 formed by the first oscillator 20 and the second oscillator 30 is a truncated cone with a large top and a small bottom. A minimum spiral diameter of the first conical spiral metal wire (i.e., the first oscillator 20) is greater than a maximum spiral diameter of the second conical spiral metal wire (i.e., the second oscillator 30).

In some embodiments, as shown in FIGS. 5-8, the PCB 10 is a trapezoidal board with a smaller top and a larger bottom, that is, the width of the upper part of the PCB 10 is smaller than the width of the lower part of the PCB 10. The dipole antenna 100 formed by the first oscillator 20 and the second oscillator 30 is a truncated cone with a smaller top and a larger bottom. The maximum spiral diameter of the first conical spiral metal wire (i.e., the first oscillator 20) is smaller than the minimum spiral diameter of the second conical spiral metal wire (i.e., the second oscillator 30).

Further, referring to FIGS. 5-8, the first conical spiral metal wire and the second conical spiral metal wire are located on a same conical surface, which not only increases aesthetics of the dipole antenna 100, but also makes the structure of the dipole antenna 100 more stable.

In some embodiments, as shown in FIGS. 5-8, in order to facilitate arrangement of the first oscillator 20 and the second oscillator 30, a first positioning member 15 and a second positioning member 16 are provided between the upper part and the lower part of the PCB 10, where the first oscillator 20 spirally extends from the first positioning member 15 toward the upper end of the PCB 10 and the second oscillator 30 spirally extends from the second positioning member 16 toward the lower end of the PCB 10. In some embodiments, the feeding end 21 of the first oscillator 20 is fixed at the first positioning member 15 and the free end of the first oscillator 20 spirally extends from the first positioning member 15 toward the upper end of the PCB 10 along the upper part of the PCB 10, and the feeding end 31 of the second oscillator 30 is fixed at the second positioning member 16 and the free end of the second oscillator 30 spirally extends from the second positioning member 16 toward the lower end of the PCB 10 along the lower part of the PCB 10.

In some embodiments, the first positioning member 15 and the second positioning member 16 may be provided at different sides of the PCB 10. For example, the first positioning member 15 is provided at the front of the PCB 10 and the second positioning member 16 is provided at the back of the PCB 10.

In some embodiments, in order to facilitate connecting with the coaxial line, the first positioning member 15 and the second positioning member 16 are provided at a same side of the PCB 10, e.g., both on the front of the PCB 10, or both on the back of the PCB 10.

In some embodiments, as shown in FIG. 5, to further facilitate connecting the feeding end 21 of the first oscillator 20 and the feeding end 31 of the second oscillator 30 with the coaxial line 40, the first pad 12 is disposed at the first positioning member 15 and the second pad 13 is disposed at the second positioning member 16.

In some embodiments, as shown in FIG. 5 and FIG. 8, a height of the cone-shaped dipole antenna 100 is 10 mm, a diameter of an upper end of the dipole antenna 100 is 4 mm, and a diameter of a lower end of the dipole antenna 100 is 8 mm. An operation frequency band of the dipole antenna 100 is 2.4 GHz to 2.5 GHz, and the height of the dipole antenna 100 is only 1/12 of the wavelength corresponding to the operation frequency band.

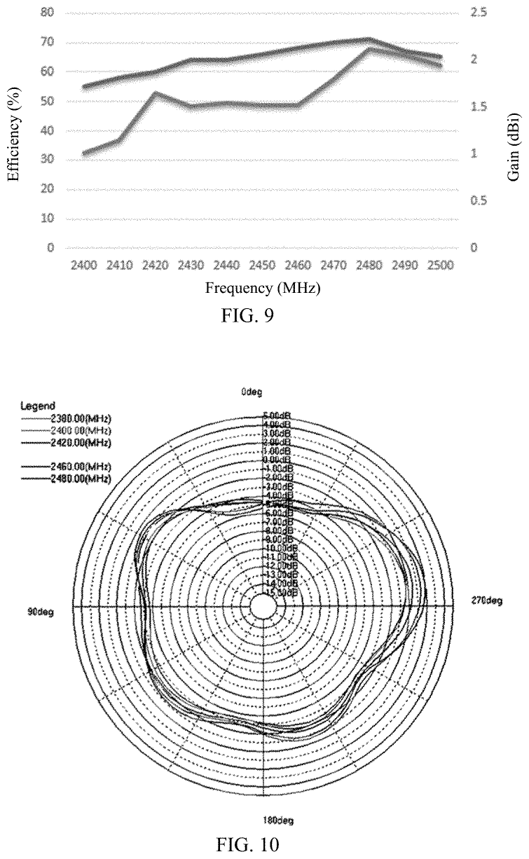

FIG. 9 is a measured efficiency diagram of the dipole antenna described above, indicating the dipole antenna 100 has an efficiency of more than 50% and a gain greater than 1 dBi in the operation frequency band of 2.4 GHz to 2.5 GHz. FIG. 10 is a measured pattern of the dipole antenna, indicating the radiation pattern of the dipole antenna 100 in a horizontal plane has an out-of-roundness of less than 6 dB.

In the dipole antenna provided by some embodiments of the present disclosure, the second oscillator is spirally wound around the outer side of the PCB, so that the dipole antenna formed by the spiral first oscillator and the spiral second oscillator has a high radiation efficiency and a good out-of-roundness in a horizontal plane, and has a simple structure, which is easy to process and manufacture, thereby reducing a manufacturing cost of the dipole antenna.

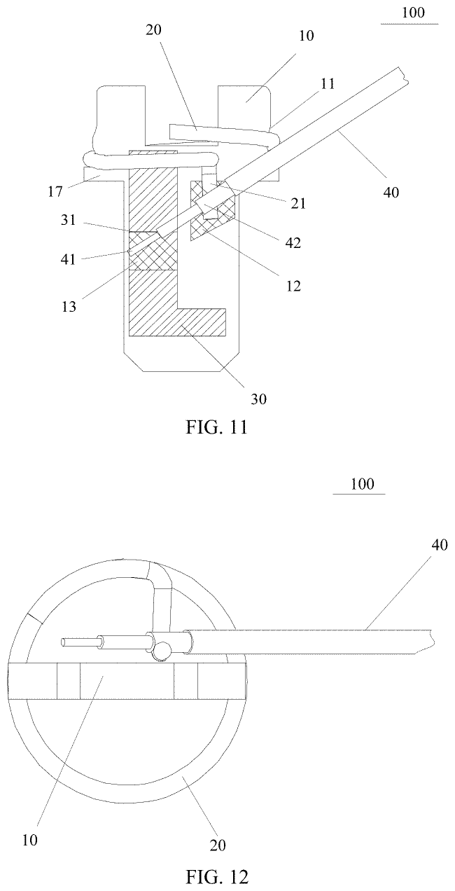

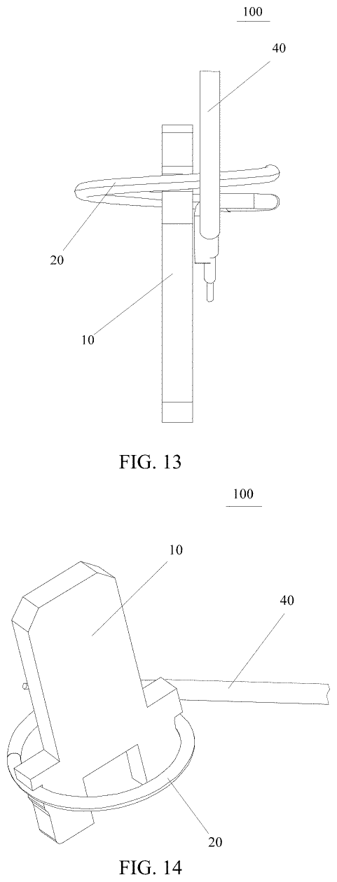

FIG. 11 is a front view of the second oscillator of another example dipole antenna consistent with the present disclosure. FIG. 12 is a top view of the second oscillator. FIG. 13 is a left side view of the second oscillator. FIG. 14 is a three-dimension diagram of the second oscillator.

In some embodiments, the second oscillator 30 includes a planar printed antenna (PPA) provided at the PCB 10. In some embodiments, as shown in FIGS. 11-14, the first oscillator 20 includes a helical antenna that is spirally wound on the PCB 10, and the second oscillator 30 includes a PPA provided at the PCB 10. The dipole antenna 100 formed by the first oscillator 20 and the second oscillator 30 has a small volume and light weight, which further meets the need for miniaturization of the UAV.

In some embodiments, a position of the second oscillator 30 does not interfere with a position of the first oscillator 20, and the second oscillator 30 may be disposed at any position of the PCB 10, e.g., the upper part of the PCB 10, the lower part of the PCB 10, or the middle of the PCB 10, thereby facilitating an arrangement of the second oscillator 30.

In some embodiments, for convenience of a subsequent wiring, as shown in FIGS. 11-14, the first oscillator 20 is wound around the upper end of the PCB 10, and the second oscillator 30 is disposed at the lower end of the PCB 10. The first oscillator 20 and the second oscillator 30 are staggered on the PCB 10 to facilitate the subsequent wiring.

In some embodiments, the second oscillator 30 may be T-shaped, umbrella-shaped, etc. In some embodiments, as shown in FIG. 11, the second oscillator 30 is L-shaped.

Further, referring to FIGS. 11-14, in order to fix the first oscillator 20, a stopper 17 that extends outward is provided between the lower part and the upper part of the PCB 10. A bottom of the first oscillator 20 (i.e., the location of the feeding end 21) abuts on the stopper 17, and a top of the first oscillator 20 (i.e., the location of the free end) spirally extends toward the upper end of the PCB 10.

In some embodiments, the free end of the first oscillator 20 is located at the top of the first oscillator 20, and the feeding end of the first oscillator 20 is located at the bottom of the first oscillator 20.

In some embodiments, the stopper 17 that extends outward is provided between the lower part and the upper part of the PCB 10. Take the stopper 17 as a dividing line, the first oscillator 20 is disposed above the stopper 17. In some embodiments, the bottom of the first oscillator 20 abuts on the stopper 17, and the top of the first oscillator 20 spirally extends toward the upper end of the PCB 10. The second oscillator 30 is disposed below the stopper 17, in some embodiments on the lower part of the PCB 10.

In some embodiments, in order to facilitate connecting the first oscillator 20 and the second oscillator 30 with the coaxial line 40, the first pad 12 and the second pad 13 may be disposed at the lower part of the PCB 10.

In some other embodiments, the second pad 13 may be provided at the second oscillator 30.

In some embodiments, as shown in FIGS. 11-14, a height of the dipole antenna 100 is 12 mm, and a diameter of the spiral formed by the first oscillator 20 is 8 mm. An operation frequency band of the dipole antenna 100 is 2.4 GHz to 2.5 GHz, and the height of the dipole antenna 100 is only 1/10 of the wavelength corresponding to the operation frequency band.

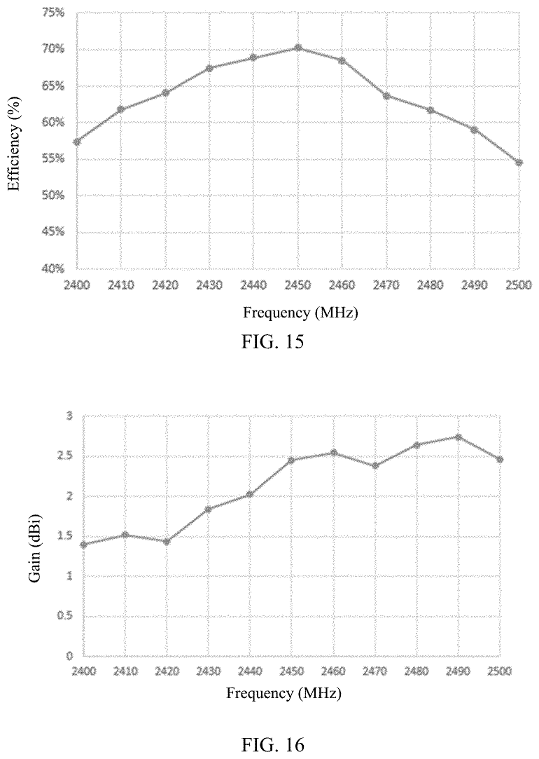

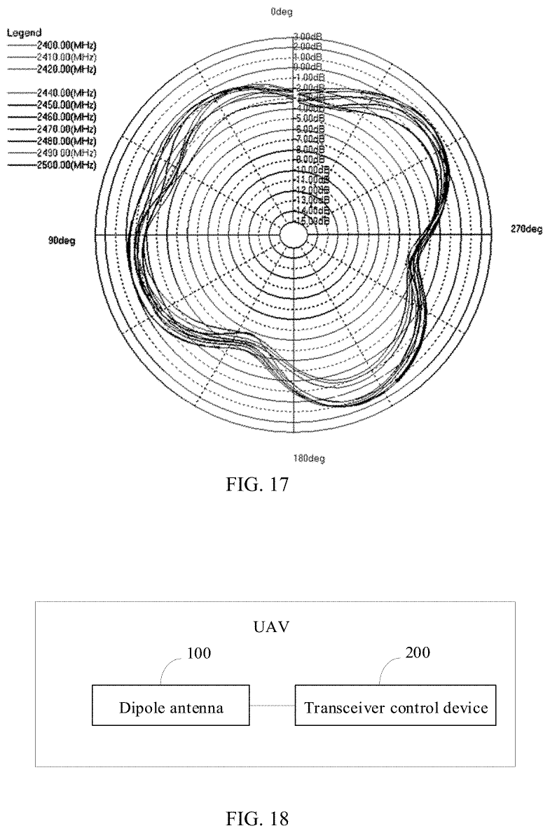

FIG. 15 is a measured efficiency diagram of the dipole antenna described above, indicating the dipole antenna 100 has an efficiency of more than 55% with a maximum value of 70% in the operation frequency band of 2.4 GHz to 2.5 GHz. FIG. 16 is a measured gain diagram of the dipole antenna, showing a gain between 1.5 dBi and 2.8 dBi that can meet a need for using on a micro UAV. FIG. 17 is a measured pattern of the dipole antenna, indicating the radiation pattern of the dipole antenna 100 in a horizontal plane has an out-of-roundness of less than 6 dB.

In some embodiments, the second oscillator is a planar printed antenna (PPA) provided at the PCB, so that the dipole antenna formed by the first oscillator and the second oscillator has a small volume and light weight, which further meets the need for miniaturization of the UAV. In addition, the dipole antenna has a good out-of-roundness in a horizontal plane, which improves an accuracy of communication between the UAV and other devices.

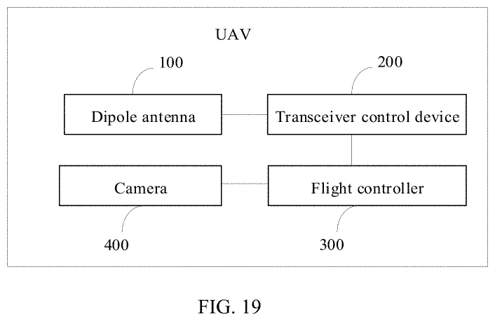

FIG. 18 is a schematic structural diagram of an example unmanned aerial vehicle (UAV) consistent with the present disclosure. FIG. 19 is a schematic structural diagram of another example unmanned aerial vehicle consistent with the disclosure. As shown in FIG. 18 and FIG. 19, the UAV includes a transceiver control device 200 and the dipole antenna 100 described in the above embodiments.

The dipole antenna 100 is electrically coupled to the transceiver control device 200, and communicates with a ground control station under control of the transceiver control device 200. For example, when the ground control station needs to control the UAV, the ground control station sends a control signal to the UAV in a form of an electromagnetic wave. The dipole antenna 100 receives the control signal sent by the ground control station under the controlling of the transceiver control device 200. The UAV sends a response signal to the ground control station through the dipole antenna 100.

In some embodiments, the UAV further includes a housing, a power system, a transmission system, and a control system, etc.

Further, as shown in FIG. 19, the UAV includes a flight controller 300 that is coupled to the transceiver control device 200. In some embodiments, the transceiver control device 200 is configured to control the dipole antenna 100 to receive the control signal sent by the ground control station and send the control signal to the flight controller 300. The flight controller 300 is configured to control the UAV according to the control signal.

For example, when the ground control station needs the UAV to reach point A from current point B within 2 minutes, the ground control station includes corresponding instruction information into a control signal and sends the control signal to the UAV. The transceiver control device 200 of the UAV controls the dipole antenna 100 to receive the control signal and sends the control signal to the flight controller 300. After receiving the control signal, the flight controller 300 parses the control signal to obtain the instruction information instructing the UAV to fly from the current point B to point A within 2 minutes. The flight controller 300 then controls the power system of the UAV to perform a corresponding action according to the parsed instruction information and drive the UAV to reach point A within 2 minutes.

In some embodiments, the UAV is for aerial photography and, as shown in FIG. 19, further includes a camera 400. The camera 400 is coupled to the flight controller 300 to perform aerial photography under the control of the flight controller 300, form an image signal, and send the image signal to the flight controller 300. In some embodiments, the flight controller 300 is configured to control the transceiver control device 200 to send the image signal to the ground control station through the dipole antenna 100, thereby realizing an actual transmission of the image.

The present disclosure has been described with the above embodiments, but the technical scope of the present disclosure is not limited to the scope described in the above embodiments. Other embodiments of the disclosure will be apparent to those skilled in the art from consideration of the specification and practice of the embodiments disclosed herein. It is intended that the specification and examples be considered as example only and not to limit the scope of the disclosure, with a true scope and spirit of the invention being indicated by the claims.

What is claimed is:

1. An unmanned aerial vehicle (UAV) comprising:
a transceiver control device; and
a dipole antenna electrically coupled to the transceiver control device and configured to communicate with a ground control station under a control of the transceiver control device, the dipole antenna including:
a printed circuit board (PCB);
a first oscillator spirally wound around an outer side of the PCB; and
a second oscillator, the first oscillator and the second oscillator forming a half-wave dipole antenna.

2. The UAV of claim 1, wherein the first oscillator is spirally wound around an upper part of the PCB and extends toward an upper end of the PCB.

3. The UAV of claim 2, wherein:
the PCB includes a groove at a side wall of the upper part of the PCB; and
the first oscillator includes a spiral metal wire fixed in the groove.

4. The UAV of claim 3, wherein the spiral metal wire includes a metal spring.

5. The UAV of claim 1, wherein the first oscillator and the second oscillator are fed through a coaxial line.

6. The UAV of claim 5, wherein the PCB includes:
a first pad, a feeding end of the first oscillator and the coaxial line being soldered on the first pad; and
a second pad, a feeding end of the second oscillator and the coaxial line being soldered on the second pad.

7. The UAV of claim 6, wherein the first pad and the second pad are located on a same side of the PCB.

8. The UAV of claim 5, wherein:
a feeding end of the first oscillator is connected to one of an inner conductor and an outer conductor of the coaxial line; and
a feeding end of the second oscillator is connected to another one of the inner conductor and the outer conductor.

9. The UAV of claim 1, wherein the second oscillator is spirally wound around an outer side of a lower part of the PCB and extends toward a lower end of the PCB.

10. The UAV of claim 9, wherein:
the PCB includes a groove at a side wall of the lower part of the PCB; and
the second oscillator includes a spiral metal wire fixed in the groove.

11. The UAV of claim 10, wherein the spiral metal wire includes a metal spring.

12. The UAV of claim 1, wherein:
the PCB includes a trapezoidal PCB;
the first oscillator includes a first conical spiral metal wire wound around an upper part of the PCB; and
the second oscillator includes a second conical spiral metal wire wound around a lower part of the PCB.

13. The UAV of claim 12, wherein the first conical spiral metal wire and the second conical spiral metal wire are located on a same conical surface.

14. The UAV of claim 12, wherein:
a width of the upper part of the PCB is smaller than a width of the lower part of the PCB; and
a maximum spiral diameter of the first conical spiral metal wire is smaller than a minimum spiral diameter of the second conical spiral metal wire.

15. The UAV of claim 1, wherein:
the PCB includes a first positioning member and a second positioning member between an upper part and a lower part of the PCB;
the first oscillator spirally extends from the first positioning member toward an upper end of the PCB; and
the second oscillator spirally extends from the second positioning member toward a lower end of the PCB.

16. The UAV of claim 15, wherein the PCB includes:
a first pad arranged at the first positioning member, a feeding end of the first oscillator being soldered on the first pad; and
a second pad arranged at the second positioning member, a feeding end of the second oscillator being soldered on the second pad.

17. The UAV of claim 1, wherein:
the first oscillator is arranged at an upper part of the PCB; and
the second oscillator includes a planar printed antenna arranged at a lower part of the PCB.

18. The UAV of claim 17, wherein the second oscillator has an L-shape.

19. The UAV of claim 17, wherein:
the PCB includes a first pad and a second pad disposed at the lower part of the PCB; and
the second pad is arranged at the second oscillator.

20. The UAV of claim 19, wherein the second oscillator, the first pad, and the second pad are located on a same side of the PCB.
